(19) United States
(12) Patent Application Publication
(10) Pub. No.: US 2024/0154022 A1
(43) Pub. Date: May 9, 2024

(54) ETCHING PROCESS WITH PROTECTED REGION

(71) Applicant: Taiwan Semiconductor Manufacturing Company, Ltd., Hsinchu (TW)

(72) Inventors: Wei-Chieh Ho, Hsinchu (TW); Po-Cheng Wang, Kaohsiung (TW); De-Fang Chen, Hsinchu (TW); Chao-Cheng Chen, Hsinchu (TW)

(73) Assignee: Taiwan Semiconductor Manufacturing Company, Ltd., Hsinchu (TW)

(21) Appl. No.: 18/165,669

(22) Filed: Feb. 7, 2023

Related U.S. Application Data
(60) Provisional application No. 63/383,016, filed on Nov. 9, 2022.

(51) Int. Cl. H01L 29/66; H01L 21/8238

(52) U.S. Cl. CPC H01L 29/6653; H01L 21/823814; H01L 21/823878; H01L 29/66439; H01L 29/66742; H01L 21/76224

(57) ABSTRACT

A method for manufacturing a semiconductor device includes forming a first fin structure and a second fin structure, wherein an isolation region is located between the fin structures, and wherein a space is located between the fin structures and above the isolation region; depositing a blocking layer over the first fin structure, the isolation region, and the second fin structure, wherein an upper portion of the blocking layer is located above the first fin structure and the second fin structure, and wherein a lower portion of the blocking layer fills the space located between the first fin structure and the second fin structure; removing the upper portion of the blocking layer; and while the lower portion of the blocking layer remains over the isolation region, performing an etch process to recess the first fin structure and the second fin structure.

### CROSS-REFERENCE TO RELATED APPLICATIONS

This application claims the benefit of U.S. Provisional Application No. 63/383,016, filed Nov. 9, 2022, which is incorporated herein by reference in its entirety.

### BACKGROUND

As the semiconductor industry has progressed into nanometer technology process nodes in pursuit of higher device density, higher performance, and lower costs, challenges from both fabrication and design issues have resulted in the development of three-dimensional designs, such as a multi-gate field effect transistor (FET), including a fin FET (Fin FET) and a gate-all-around (GAA) FET. In a Fin FET, a gate electrode is adjacent to three side surfaces of a channel region with a gate dielectric layer interposed therebetween. Because the gate structure surrounds (wraps) the fin on three surfaces, the transistor essentially has three gates controlling the current through the fin or channel region. Unfortunately, the fourth side, the bottom part of the channel is far away from the gate electrode and thus is not under close gate control. In contrast, in a GAA FET, all side surfaces of the channel region are surrounded by the gate electrode, which allows for fuller depletion in the channel region and results in less short-channel effects due to steeper sub-threshold current swing (SS) and smaller drain induced barrier lowering (DIBL). As transistor dimensions are continually scaled down to sub 10-15 nm technology nodes, further improvements of the GAA FET are required.

### BRIEF DESCRIPTION OF THE DRAWINGS

Aspects of the present disclosure are best understood from the following detailed description when read with the accompanying figures. It should be noted that, in accordance with the standard practice in the industry, various features may not be drawn to scale. In fact, the dimensions of the various features may be arbitrarily increased or reduced for clarity of discussion.

FIG. 1 is a flow chart illustrating a method in accordance with some embodiments.

FIGS. 2-4 are perspective view of successive stages of manufacturing a semiconductor device in accordance with some embodiments.

FIGS. 5-10 are cross-sectional views of the semiconductor device of FIGS. 1-4 taken along a “Y-cut”, or a plane substantially parallel to a Y-axis of FIG. 2, during sequential fabrication stages in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting.

For the sake of brevity, conventional techniques related to conventional semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many conventional processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

Furthermore, spatially relative terms, such as “over”, “overlying”, “above”, “upper”, “top”, “under”, “underlying”, “below”, “lower”, “bottom”, and the like, may be used herein for ease of description to describe one element's or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When a spatially relative term, such as those listed above, is used to describe a first element with respect to a second element, the first element may be directly on the other element, or intervening elements or layers may be present. When an element or layer is referred to as being “on” another element or layer, it is directly on and in contact with the other element or layer.

As used herein, a “material layer” or a layer that is a “material” includes at least 50 wt. % of the identified material, for example at least 60 wt. % of the identified material, such at least 75 wt. % of the identified material or at least 90 wt. % of the identified material. For example, each of a germanium layer and a layer that is germanium is a layer that is at least 50 wt. %, at least 60 wt. %, at least 75 wt. %, or at least 90 wt. % germanium.

In addition, the present disclosure may repeat reference numerals and/or letters in the various examples. This repetition is for the purpose of simplicity and clarity and does not in itself dictate a relationship between the various embodiments and/or configurations discussed.

The present disclosure is generally related to semiconductor devices and methods of forming the same. Various embodiments are discussed herein in a particular context, namely, in the context of a gate-all-around (GAA) FET or device. However, it is noted that the present disclosure is not limited to use in processes for fabricating GAA devices.

A GAA device includes any device that has its gate structure, or portions thereof, formed on four-sides of a channel region (e.g., surrounding a portion of a channel region). The channel region of a GAA device may include nanowire channels, bar-shaped channels, and/or other suitable channel configurations. In certain embodiments, GAA devices are formed by alternately stacking first and second semiconductor layers over a semiconductor substrate, selectively removing one type of semiconductor layers to create a void around the other type of semiconductor layers, and filling the void with gate material.

In embodiments, the channel region of a GAA device may have multiple horizontal nanowires or horizontal bars vertically spaced, making the GAA device a stacked horizontal GAA (S-HGAA) device. The GAA devices presented herein may include p-type metal-oxide-semiconductor GAA devices or n-type metal-oxide-semiconductor GAA devices. Further, the GAA devices may have one or more channel regions (e.g., nanowires) associated with a single, contiguous gate structure, or multiple gate structures. One of ordinary skill may recognize other examples of semiconductor devices that may benefit from aspects of the present disclosure.

In processing, fin structures may be formed over a substrate and isolation regions may be formed adjacent to the fin structures. Further, dummy gate structures may be formed over the fin structures, thereby defining gate regions and source/drain regions. In source/drain regions of the fin structures, strained source/drains may be formed by first etching the fin structures to form cavities, and then by epitaxially growing source/drain material in the cavity. During this etch process, the isolation region between fin structures may be etched or otherwise damaged. For example, the semiconductor substrate material under the isolation region may be exposed. Exposed semiconductor material during the formation of the source/drains may cause the growth of epitaxial material from one fin structure toward an adjacent fin structure, or even a merger of the epitaxial material between adjacent fin structures. Merger of epitaxial material between adjacent fin structures may be of particular concern in PMOS structures.

Embodiments herein protect the isolation region from being etched or otherwise damaged during the etch process for forming source/drain cavities. As a result, the process for epitaxially growing source/drain material in the source/drain cavity does not result in the merger of epitaxial material between adjacent fin structures. In certain embodiments, the process for forming strained source/drain regions results in zero loss of isolation material adjacent the source/drain regions. As a result, fabrication yield may be improved using processes described herein.

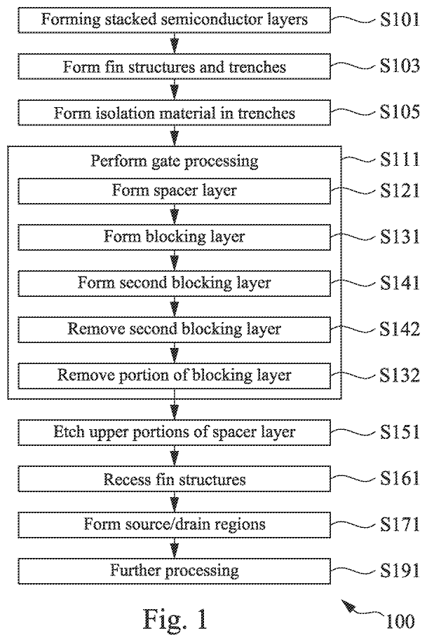

For purposes of the discussion that follows, FIG. 1 provides a flow chart of a method 100 for manufacturing a semiconductor device, in accordance with various embodiments. Method 100 is discussed below with reference to a GAA device formed with a replacement gate process. However, it will be understood that aspects of method 100 may be equally applied to other types of structures or processes without departing from the scope of the present disclosure. It is understood that method 100 includes steps having features of a complementary metal-oxide-semiconductor (CMOS) technology process flow and thus, are only described briefly herein. Also, additional steps may be performed before, after, and/or during method 100.

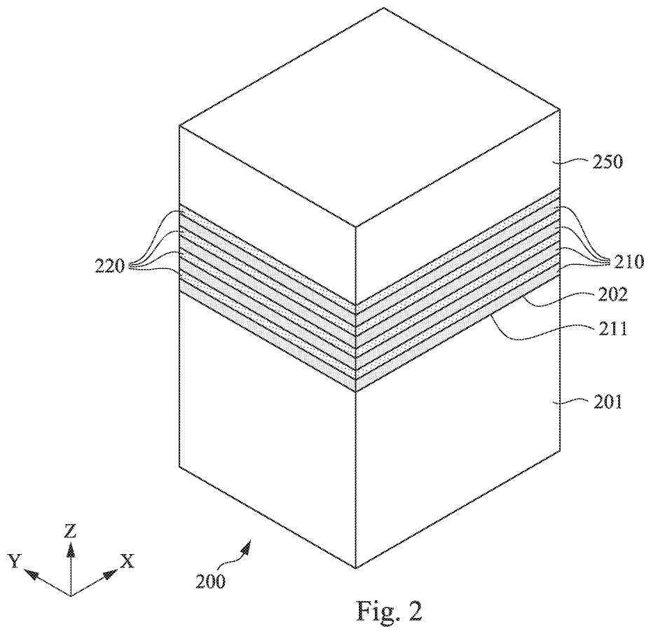

Method 100 is described below with initial reference to FIG. 2, which illustrates a stage of fabrication of a semiconductor device 200. Cross-referencing FIGS. 1 and 2, action S101 of method 100 includes forming stacked semiconductor layers over a semiconductor substrate 201. The stacked semiconductor layers include first semiconductor layers 210 and second semiconductor layers 220.

In some embodiments, the semiconductor substrate 201 includes a single crystalline semiconductor layer on at least a surface portion. The substrate 201 may comprise a single crystalline semiconductor material such as, but not limited to Si, Ge, SiGe, GaAs, InSb, GaP, GaSb, InAlAs, InGaAs, GaSbP, GaAsSb and InP. In certain embodiments, the substrate 201 is made of crystalline Si.

The substrate 201 may include in its surface region, one or more buffer layers (not shown). The buffer layers can serve to gradually change the lattice constant from that of the substrate to that of the source/drain regions. The buffer layers may be formed from epitaxially grown single crystalline semiconductor materials such as, but not limited to Si, Ge, GeSn, SiGe, GaAs, InSb, GaP, GaSb, InAlAs, InGaAs, GaSbP, GaAsSb, GaN, GaP, and InP. In a particular embodiment, the substrate 201 comprises silicon germanium (SiGe) buffer layers epitaxially grown on the silicon substrate 201. The germanium concentration of the SiGe buffer layers may increase from 30 atomic % germanium for the bottom-most buffer layer to 70 atomic % germanium for the top-most buffer layer.

In some embodiments, impurity ions (dopants) are implanted into a silicon substrate 201 to form a well region. The ion implantation is performed to prevent a punch-through effect. The substrate 201 may include various regions that have been suitably doped with impurities (e.g., p-type or n-type conductivity). The dopants are, for example boron (BF₂) for an n-type Fin FET and phosphorus for a p-type Fin FET.

In certain embodiments, the first semiconductor layers 210 and the second semiconductor layers 220 are made of materials having different lattice constants, and may include one or more layers of Si, Ge, SiGe, GaAs, InSb, GaP, GaSb, InAlAs, InGaAs, GaSbP, GaAsSb or InP.

In some embodiments, the first semiconductor layers 210 and the second semiconductor layers 220 are made of Si, a Si compound, SiGe, Ge or a Ge compound.

In FIG. 2, four layers of the first semiconductor layer 210 and four layers of the second semiconductor layer 220 are disposed. However, the number of the layers are not limited to four, and may be as small as one (each layer) and in some embodiments, two to ten layers of each of the first and second semiconductor layers are formed. By adjusting the numbers of the stacked layers, a driving current of the GAA FET device can be adjusted.

In certain embodiments, the first semiconductor layers 210 and the second semiconductor layers 220 are epitaxially formed over the substrate 201. The thickness of the first semiconductor layers 210 may be equal to or greater than that of the second semiconductor layers 220. For example, the thickness of the first semiconductor layers 210 may be from 2 to 20 nm in some embodiments, and from 5 to 15 nm in some embodiments. The thickness of the second semiconductor layers 220 may be from 2 to 20 nm in some embodiments, and from 5 to 15 nm in some embodiments. The thickness of each of the semiconductor layers 210, 220 may be the same, or may vary.

In some embodiments, the bottom first semiconductor layer 211 (the closest layer to the substrate 201) is thicker than the remaining first semiconductor layers. The thickness of the bottom first semiconductor layer 211 may be from 10 to 50 nm in some embodiments, or from 20 to 40 nm in some embodiments.

As shown in FIG. 2, an interface 202 is defined between the bottom first semiconductor layer 211 and the semiconductor substrate 201.

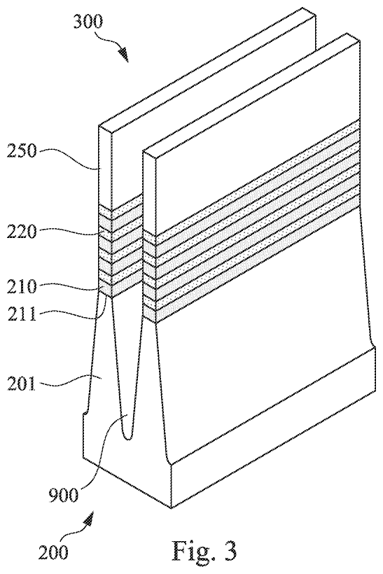

Cross referencing FIGS. 1-3, action S103 of method 100 includes forming fin structures 300 from the stacked semiconductor layers and a portion of the semiconductor substrate 201. Specifically, trenches 900 are etched through the stacked semiconductor layers and into the semiconductor substrate 201.

As shown, a mask 250 is formed over the stacked layers 210 and 220. In some embodiments, the mask layer 250 includes a first mask layer and a second mask layer. The first mask layer may be a pad oxide layer made of a silicon oxide, which can be formed by a thermal oxidation. The second mask layer may be made of a silicon nitride (SiN), which is formed by chemical vapor deposition (CVD), including low pressure CVD (LPCVD) and plasma enhanced CVD (PECVD), physical vapor deposition (PVD), atomic layer deposition (ALD), or other suitable process.

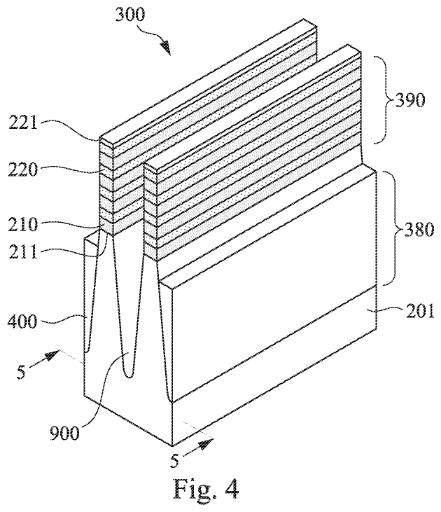

As shown in FIG. 4, the mask layer may be patterned into a mask pattern by using patterning operations including photolithography and etching. As further shown in FIG. 4, action S103 includes patterning the stacked layers of the first and second semiconductor layers 210, 220 by using the patterned mask layer, thereby the stacked layers are formed into fin structures 300 extending in the X direction. In FIG. 4, two fin structures 300 are distanced from one another in the Y direction. But the number of the fin structures is not limited to two, and may be as small as one and three or more. In some embodiments, one or more dummy fin structures are formed on both sides of the fin structures 300 to improve pattern fidelity in the patterning operations.

As shown in FIG. 4, the fin structures 300 have upper portions 390 constituted by the stacked semiconductor layers 210 and 220. Further, the fin structures 300 have lower portions 380 or well portions formed from the semiconductor substrate 201. Thus, an exemplary fin structure 300 includes alternately stacked first and second semiconductor layers 210 and 220 as well as an upper portion of semiconductor substrate 201.

The thickness or width of the upper portion 390 of the fin structure 300 (in the Y direction) may be from 10 to 40 nm in some embodiments and may be from 20 to 30 nm in some embodiments. The height of the upper portion 390 of each fin structure 300 (in the Z direction, i.e., perpendicular to the substrate 201) may be from 100 to 200 nm in some embodiments.

The stacked fin structure 300 may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the stacked fin structure 300.

Cross-referencing FIGS. 1 and 4, method 100 may continue with action S105, in which, an isolation material 400, that may include one or more layers of insulating material, is formed over the substrate 201 and in the trenches 900 so that the fin structures 300 are fully embedded in the isolation material 400. The insulating material for the insulating layer may include silicon oxide, silicon nitride, silicon oxynitride (SiON), SiOCN, SiCN, fluorine-doped silicate glass (FSG), or a low-K dielectric material, formed by LPCVD (low pressure chemical vapor deposition), plasma-CVD or flowable CVD. An anneal operation may be performed after the formation of the insulating layer.

Then, a planarization operation, such as a chemical mechanical polishing (CMP) method and/or an etch-back method, is performed such that the upper surface of the top second semiconductor layer 221 is exposed from the insulating material layer. In some embodiments, a fin liner layer may be formed over the fin structures before forming the isolation material 400. Such a fin liner layer may be is made of SiN or a silicon nitride-based material (e.g., SiON, SiCN or SiOCN).

Then, as shown in FIG. 4, the insulating material layer is recessed to define the isolation material 400 in the trenches 900 so that the upper portions 390 of the fin structures 300 are exposed. With this operation, the fin structures 300 are electrically separated from each other by the isolation material 400, which is also called a shallow trench isolation (STI).

In the embodiment shown in FIG. 4, the insulating material layer may be recessed so that the bottom first semiconductor layer 211 is not covered by the isolation material 400. In gate regions, the first semiconductor layers 210 are sacrificial layers which are subsequently partially removed, and the second semiconductor layers 220 are subsequently formed into semiconductor wires as channel layers of a GAA FET.

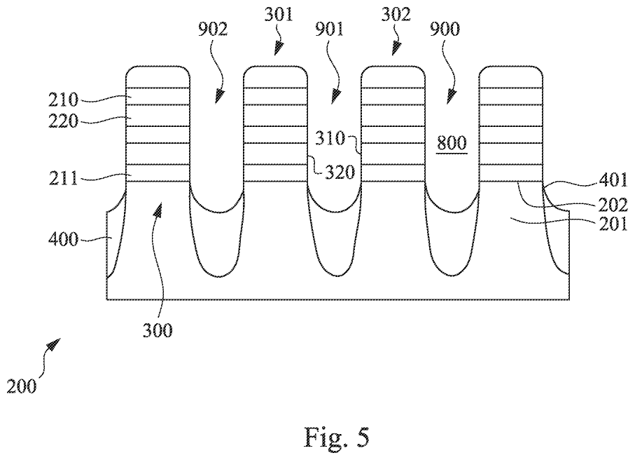

FIG. 5 is a “Y cut” cross-sectional view of the partially fabricated structure 200 of FIG. 4, taken along line 5-5 in FIG. 4. FIG. 5 illustrates four fin structures 300, each having three first semiconductor layers 210 and three second semiconductor layers 220 for purposes of discussion. As noted above, there may be as few as one fin structure 300 or many fin structures 300, having as few as one of each semiconductor layers 210 and 220 or many semiconductor layers 210 and 220.

As shown in FIG. 5, the fin structures 300 include a fin structure 301 and a fin structure 302, and the trenches 900 include a trench 901 and trench 902. Further, each fin structure 300 has a sidewall 310 and a second sidewall 320. Trenches 900 are defined between adjacent fin structures 300. For example, trench 901 is located between the sidewall 320 of the fin structure 301 and the sidewall 310 of the fin structure 302. In other words, sidewall 320 of structure 301 faces and is separated from sidewall 310 of the structure 302 by trench 901. Further, spaces or gaps 800 are defined between adjacent fin structures 300 above the isolation material 400.

As shown in FIG. 5, after forming the isolation material 400 in the trench 900, the isolation material 400 has an uppermost surface 401 that is lower than each interface 202 between the bottom first semiconductor layer 211 and the semiconductor substrate 201.

After the isolation material 400 is formed in the trenches 900, method 100 may continue with gate processing at action S111. For example, gate processing S111 may include forming sacrificial (dummy) gate structures over the exposed fin structures 300. The sacrificial gate structure may be formed over a portion of the fin structures 300 which is to be a channel region. The sacrificial gate structures define the channel regions of the GAA FET. In exemplary embodiments, the sacrificial gate structure extends in the X direction, perpendicular to the fin structures 300, and are distanced from one another in the Y direction.

The sacrificial gate structure may include a sacrificial gate dielectric layer and a sacrificial gate electrode layer. The sacrificial gate dielectric layer may include one or more layers of insulating material, such as a silicon oxide-based material. In one embodiment, silicon oxide formed by CVD is used.

The sacrificial gate structure may be formed by first blanket depositing a sacrificial gate dielectric layer over the fin structures. A sacrificial gate electrode layer is then blanket deposited on the sacrificial gate dielectric layer and over the fin structures, such that the fin structures are fully embedded in the sacrificial gate electrode layer. The sacrificial gate electrode layer includes silicon such as polycrystalline silicon or amorphous silicon. The thickness of the sacrificial gate electrode layer is in a range from about 100 nm to about 200 nm in some embodiments. In some embodiments, the sacrificial gate electrode layer is subjected to a planarization operation. The sacrificial gate dielectric layer and the sacrificial gate electrode layer are deposited using CVD, including LPCVD and PECVD, PVD, ALD, or other suitable process. Subsequently, a mask layer is formed over the sacrificial gate electrode layer. The mask layer may include a pad SiN layer and a silicon oxide mask layer.

Further, gate processing S111 may include performing a patterning operation on the mask layer and then patterning of the sacrificial gate electrode layer to form the sacrificial gate structure. The sacrificial gate structure includes the sacrificial gate dielectric layer, the sacrificial gate electrode layer (e.g., poly silicon), the pad SiN layer and the silicon oxide mask layer. By patterning the sacrificial gate structure, the stacked layers of the first and second semiconductor layers are partially exposed on opposite sides of the sacrificial gate structure, thereby defining source/drain (S/D) regions. In this disclosure, a source and a drain are interchangeably used, and the structures thereof are substantially the same.

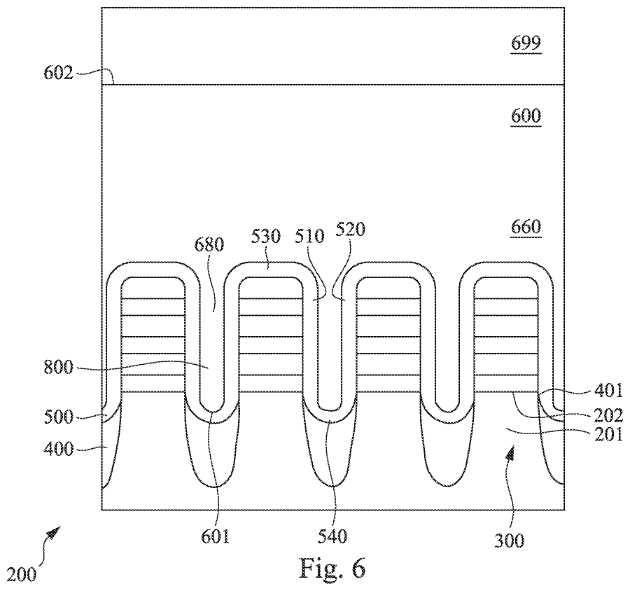

Cross-referencing FIGS. 1 and 6, the gate processing of action S111 may further include, at action S121, formation of a spacer layer 500 over the partially fabricated structure 200 of FIG. 5. Specifically, the spacer layer 500 is conformally deposited over the fin structures 300 and isolation material 400. The spacer layer 500 may further be conformally deposited over the sacrificial gate structures.

Cross-referencing FIGS. 5 and 6, the spacer layer 500 includes sidewall portions 510, each of which is laterally adjacent (i.e., in the Y direction) to a respective sidewall 310; sidewall portions 520, each of which is laterally adjacent (i.e., in the Y direction) to a respective sidewall 320; upper portions 530, each of which is directly over a respective fin structure 300; and lower portions 540, each of is directly over and covers a respective isolation material 400. Exemplary lower portions 540 extend from respective sidewall portions 510 to respective sidewall portion 520.

As shown, the spacer layer 500 is continuous, from lower portion 540 to sidewall portion 510, to upper portion 530, to sidewall portion 520, to lower portion 540, and so on, such that the partially fabricated structure 200 of FIG. 5 is completely covered by the spacer layer. In exemplary embodiments, after forming the spacer layer 500 over the fin structures 300 and isolation material 400, the spacer layer 500 is in contact with the semiconductor substrate 201 in each fin structure 300. Specifically, the spacer layer 500 contacts the semiconductor substrate 201 between the uppermost surface 401 of the isolation material and the interface 202.

In exemplary embodiments, the spacer layer 500 is formed from SiN, SiOCN, SiOC, SiO₂, or SiC. In exemplary embodiments, the spacer layer 500 has a thickness of from 1 to 20 nm, such as from 1 to 15 nm.

Cross-referencing FIGS. 1 and 6, the gate processing of action S111 may further include, at action S131, forming a bottom cover layer or blocking layer 600 in the gate region and source/drain regions. In the source/drain regions, the blocking layer 600 is formed over the spacer layer 500 overlying the partially fabricated structure 200. For example, a bottom cover layer 600 may be deposited over the spacer layer 500 overlying the fin structures 300 in source/drain regions, such as shown in FIG. 6, and over the sacrificial gate structures (not shown in the view of FIG. 6), such as by a blanket deposition process.

As shown, the blocking layer 600 includes lower or inter-structure portions 680 that are located laterally adjacent to (in the Y direction) and between respective adjacent fin structures 300. In exemplary embodiments, the inter-structure portions 680 of blocking layer 600 fill the spaces 800 located between adjacent fin structures 300. The inter-structure portions 680 extend to a bottommost edge 601 that is nearest to the semiconductor substrate 201.

Further, the blocking layer 600 includes an upper portion 660 that is located above the fin structures 300. More particularly, the upper portion 660 of the blocking layer 600 is located at a height (in the Z direction) over the semiconductor substrate 201 that is greater than the height (in the Z direction)) of the fin structures 300 over the semiconductor substrate 201. The upper portion 660 of the blocking layer 600 may be planarized to a topmost edge 602.

An exemplary blocking layer 600 has a thickness or height (in the Z direction) from the bottommost edge 601 to the topmost edge 602 of from 2000 to 3000 Angstrom (A), such as about 2400 A.

Further, the gate processing of action S111 may further include, at action S141, forming a second cover layer or blocking layer 699 over the first cover layer 600 in the gate region and source/drain regions, as shown in FIG. 6. The blocking layer 699 may be planarized after deposition. An exemplary blocking layer 699 has a thickness or height (in the Z direction) of from 200 to 600 Angstrom (A), such as about 400 A.

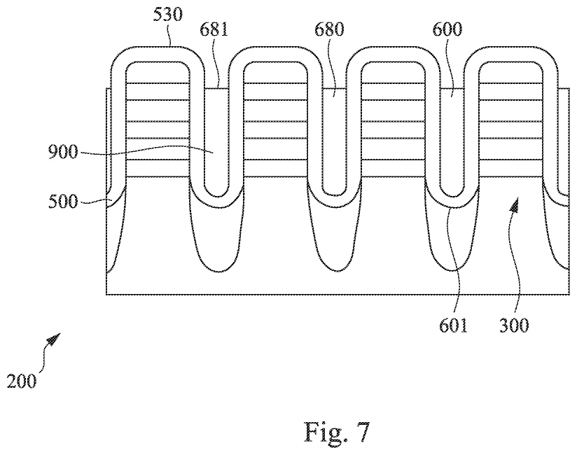

Cross-referencing FIGS. 1 and 7, the gate processing of action S111 may further include removing of the blocking layer 699 from the gate region and source/drain regions at action S142.

Further, the gate processing of action S111 may further include, at action S132, removing a portion of the blocking layer 600. For example, the blocking layer 600 is removed from the gate region and a portion of the blocking layer is removed from the source/drain regions. In certain embodiments, removing a portion of the blocking layer 600 from the source/drain regions includes removing the upper portion 660 of the blocking layer 600 to uncover the upper portions 530 of the spacer layer 500. In certain embodiments, an etch process may be performed to remove all of the upper portion 660 of the blocking layer 600 and some of the inter-structure portions 680 of the blocking layer 600. As a result, each inter-structure portion 680 of the blocking layer 600 is formed with a recessed surface 681 that is located in the respective trench 900 between fin structures 300.

In exemplary embodiments, the inter-structure portions 680 of the blocking layer 600 have a height (in the Z direction) from the bottommost edge 601 to the recessed surface 681 of at least 5 nm, at least 10 nm, at least 15 nm, at least 20 nm, at least 25 nm, at least 30 nm, at least 40 nm, at least 50 nm, at least 60 nm, at least 70 nm, at least 80 nm, at least 90 nm, or at least 100 nm; and at most 250 nm, at most 240 nm, at most 230 nm, at most 220 nm, at most 210 nm, at most 200 nm, or at most 150 nm. In exemplary embodiments, the inter-structure portions 680 of the blocking layer 600 have a height (in the Z direction) from the bottommost edge 601 to the recessed surface 681 of from 10 to 200 nm.

In an exemplary embodiment, action S132 includes etching the blocking layer 600 with a dry etch process. For example, the dry etch process may utilize N₂/O₂ gas to control the amount of blocking layer 600 that is etched. In an exemplary embodiment, the dry etch process is performed with N₂/O₂ gas at a pressure of from 3 milliTor (mTorr) to 20 mTorr, with a bias power of from 50 V to 300 V, and for a process time of from 10 seconds to 300 seconds.

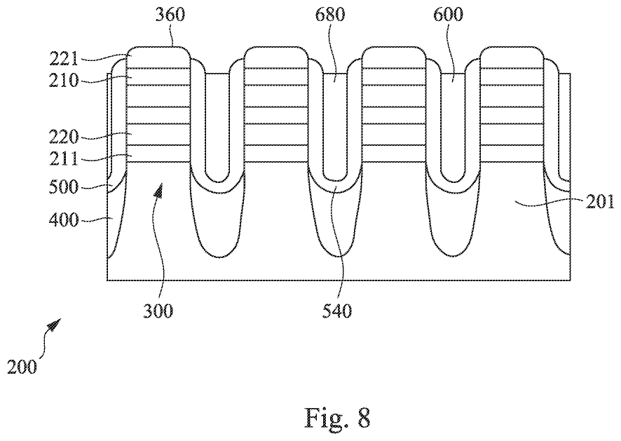

Cross-referencing FIGS. 1 and 8, method 100 may continue with, at action S151, removing the upper portions 530 of the spacer layer 500 overlaying the fin structures 300. As a result, top surfaces 360 of the fin structures 300 are uncovered and exposed. In exemplary embodiments, action S151 includes performing an etch process selective to etching the spacer layer 500 material. Further, in exemplary embodiments, the etch process is an anisotropic etching process.

While etching to remove the upper portions 530 of the spacer layer 500, the inter-structure portions 680 of the blocking layer 600 remain located over the lower portions 540 of the spacer layer 500, and over the underlying isolation regions 400. As a result, the etch performed during action S151 does not etch or damage the lower portions 540 of the spacer layer 500 or the isolation regions 400.

At the fabrication stage of FIG. 8, i.e., before performing an etch process to remove the alternately stacked first and second semiconductor layers 210 and 220 from over the semiconductor substrate 201, the alternately stacked first and second semiconductor layers have a combined height (in the Z direction) from the bottom surface of the bottom first semiconductor layer 211 to the upper surface of the top second semiconductor layer 221 of at least 15 nm, at least 20 nm, at least 25 nm, at least 30 nm, or at least 35 nm; at most 100 nm, at most 90 nm, at most 80 nm, at most 70 nm, at most 60 nm; such as from 30 to 70 nanometers (nm).

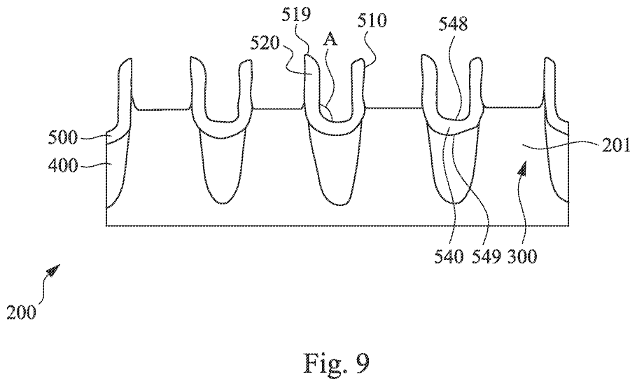

Cross-referencing FIGS. 1 and 9, method 100 further includes, at action S161, recessing the fin structures 300. For example, action S161 may include removing the upper portions 390 of the fin structures 300. Specifically, action S161 may include performing an etch process to remove the alternately stacked first and second semiconductor layers 210 and 220 from over the semiconductor substrate 201. In exemplary embodiments, action S161 is performed while the spacer layer 500 remains over the isolation material 400. In particular, action S161 is performed while the isolation region 400 is encapsulated between the semiconductor substrate 201 and the spacer layer 500 before, during and after performing the etch process to recess the fin structures 300. In exemplary embodiments, performing the etch process to recess the fin structures 300 includes removing the inter-structure portion 680 of the blocking layer 600, as shown in FIG. 9.

In exemplary embodiments, while performing the etch process to remove the alternately stacked first and second semiconductor layers 210 and 220 from over the semiconductor substrate 201, sidewall portions 510 and 520 are reduced in height.

In exemplary embodiments, after performing the etch process to remove the alternately stacked first and second semiconductor layers 210 and 220 from over the semiconductor substrate 201, the sidewall portions 510 and 520 of the spacer layer 500 are recessed and terminate at recessed uppermost surfaces 519. A maximum vertical height (i.e., in the Z direction) of the recessed sidewall portions 510 and 520 is defined from the recessed uppermost surface 519 to a bottommost surface 549 of the lower portion 540 of the spacer layer 500. In exemplary embodiments, the maximum vertical height is at least 10 nm, at least 15 nm, at least 20 nm, or at least 25 nm; at most 40 nm, at most 35 nm, at most 30 nm, or at most 25 nm; such as from 10 nm to 30 nm.

In exemplary embodiments, after performing the etch process to remove the alternately stacked first and second semiconductor layers 210 and 220 from over the semiconductor substrate 201, and as shown in FIG. 9, at a central region of each remaining lower portion 540 of the spacer layer 500 has a thickness or height (in the Z direction) from the bottommost surface 549 to the top surface 548 opposite the bottommost surface 549 of from 1 to 15 nanometers (nm).

Also, in exemplary embodiments, after performing the etch process to remove the alternately stacked first and second semiconductor layers 210 and 220 from over the semiconductor substrate 201, and as shown in FIG. 9, an internal angle A is formed between the inner surface of each lower portion 540 and the respective inner surface of the remaining portion of adjacent sidewall 510 or sidewall 520. In exemplary embodiments, the internal angle A is from 80 to 90 degrees.

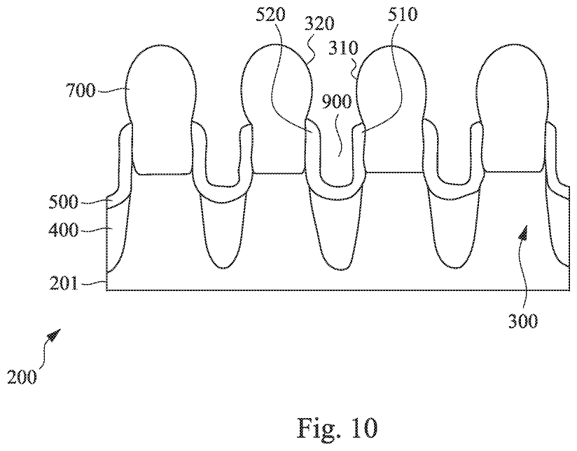

Cross-referencing FIGS. 1 and 10, method 100 may continue with action S171 which includes selectively growing epitaxial material over the semiconductor substrate 201 of fin structures 300 to form source/drain regions 700. In exemplary embodiments, the source/drain regions 700 are strained source/drain regions 700. While growing the epitaxial material, the spacer layer 500 and isolation material 400 cover the remaining sidewalls 310 and 320 to prevent epitaxial growth thereon. Further, the sidewall portions 510 and 520 of the spacer layer 500 prevents growth of epitaxial material into the trenches 900.

The epitaxial material may include one or more layers of Si, SiP, SiC and SiCP for an n-channel FET or Si, SiGe, Ge for a p-channel FET. For the P-channel FET, boron (B) may also be contained in the source/drain. The source/drain epitaxial layers may be formed by an epitaxial growth method using CVD, ALD or molecular beam epitaxy (MBE).

As shown in FIG. 1, method 100 may continue with further CMOS processing at action S191 to complete fabrication of the semiconductor device 200. Such processing may include removal of sacrificial gate structures, metal gate formation, contact/via formation, interconnect metal layers, dielectric layers, passivation layers, etc.

Methods for manufacturing semiconductor devices are provided in accordance with certain embodiments.

An exemplary method for manufacturing a semiconductor device includes forming a first structure and a second structure, each structure includes alternately stacked first and second semiconductor layers over a semiconductor substrate, a first sidewall of the first structure faces and is separated from a second sidewall of the second structure by a gap; forming an isolation material in the gap; forming a spacer layer over the first structure, the isolation material, and the second structure, the spacer layer includes a first upper portion located over the first structure, a second upper portion located over the second structure, a first sidewall portion laterally adjacent to the first sidewall, a second sidewall portion laterally adjacent to the second sidewall, and a lower portion over the isolation material and extending from the first sidewall portion to the second sidewall portion; depositing a blocking layer over the spacer layer, an upper portion of the blocking layer is located above the first structure and the second structure, and an inter-structure portion of the blocking layer is located between the first structure and the second structure; removing the upper portion of the blocking layer to uncover the first upper portion and the second upper portion of the spacer layer; and, while the spacer layer remains over the isolation material, performing an etch process to remove the alternately stacked first and second semiconductor layers from over the semiconductor substrate.

In certain embodiments of the method, the first sidewall portion and the second sidewall portion of the spacer layer are reduced in height while performing the etch process to remove the alternately stacked first and second semiconductor layers from over the semiconductor substrate.

In certain embodiments of the method, the first sidewall portion and the second sidewall portion of the spacer layer terminate at upper surfaces distanced from the lower portion by distances of from 10 to 30 nanometers (nm) after performing the etch process to remove the alternately stacked first and second semiconductor layers from over the semiconductor substrate.

In certain embodiments of the method, the lower portion of the spacer layer has a thickness in a direction perpendicular to the semiconductor substrate of from 1 to 15 nanometers (nm).

In certain embodiments of the method, the alternately stacked first and second semiconductor layers have a combined height in a direction perpendicular to the semiconductor substrate of from 30 to 70 nanometers (nm) before performing the etch process to remove the alternately stacked first and second semiconductor layers from over the semiconductor substrate.

In certain embodiments of the method, each sidewall portion of the spacer layer forms an internal angle with the lower portion of the spacer layer of from 80 to 90 degrees.

In certain embodiments of the method, the spacer layer is SiN, SiOCN, SiOC, SiO₂, or SiC.

In certain embodiments, the method further includes selectively growing epitaxial material over the semiconductor substrate of the first structure and over the semiconductor substrate of the second structure to form a source/drain regions, the spacer layer and isolation material cover the first sidewall and the second sidewall to prevent epitaxial growth thereon. In such embodiments, the method may further include removing the spacer layer after selectively growing the epitaxial material to form the source/drain regions.

In certain embodiments of the method, each structure includes an interface between a lowest second semiconductor layer and the semiconductor substrate after forming the first structure and the second structure, and the isolation material has an uppermost surface that is lower than each interface after forming the isolation material in the gap. In such embodiments, the spacer layer is in contact with the semiconductor substrate of each structure after forming the spacer layer over the first structure, the isolation material, and the second structure.

In another embodiment, a method for manufacturing a semiconductor device includes forming a structure between a first trench and a second trench, the structure has a first sidewall and a second sidewall; forming an isolation material in the first trench and in the second trench; forming a spacer layer over the structure and the isolation material, the spacer layer includes an upper portion located over the structure, a first sidewall portion laterally adjacent to the first sidewall, a second sidewall portion laterally adjacent to the second sidewall, a first trench portion over the isolation material in the first trench, and a second trench portion over the isolation material in the second trench; depositing a blocking layer over the spacer layer, an upper portion of the blocking layer is located above the structure, and a lower portion of the blocking layer is located laterally adjacent to the structure; removing the upper portion of the blocking layer to uncover the upper portion of the spacer layer; removing the upper portion of the spacer layer to uncover the structure; and performing an etch process to recess the structure, the spacer layer remains over the isolation material.

In certain embodiments of the method, forming the structure between the first trench and the second trench includes etching a semiconductor material to form the first trench and the second trench. In such embodiments, the semiconductor material includes alternately stacked first and second semiconductor layers and an underlying semiconductor substrate, and etching the first trench and the second trench includes etching the first trench and the second trench through the alternately stacked first and second semiconductor layers and into the underlying semiconductor substrate.

In certain embodiments of the method, performing the etch process to recess the structure includes recessing the first sidewall portion and the second sidewall portion of the spacer layer.

In certain embodiments of the method, performing the etch process to recess the structure includes removing the lower portion of the blocking layer.

In another embodiment, a method for manufacturing a semiconductor device includes forming a first fin structure and a second fin structure, an isolation region is located between the first fin structure and the second fin structure, and a space is located between the first fin structure and the second fin structure and above the isolation region; depositing a blocking layer over the first fin structure, the isolation region, and the second fin structure, an upper portion of the blocking layer is located above the first fin structure and the second fin structure, and a lower portion of the blocking layer fills the space located between the first fin structure and the second fin structure; removing the upper portion of the blocking layer; and while the lower portion of the blocking layer remains over the isolation region, performing an etch process to recess the first fin structure and the second fin structure

In certain embodiments, the method further includes planarizing an upper surface of the upper portion of the blocking layer; forming an upper blocking layer over the upper surface of the upper portion of the blocking layer; and removing the upper blocking layer before removing the upper portion of the blocking layer.

In certain embodiments, the method further includes forming a spacer layer over the first fin structure, the isolation region, and the second fin structure, the blocking layer is deposited over the spacer layer; and removing upper portions of the spacer layer to uncover the first fin structure and the second fin structure after removing the upper portion of the blocking layer.

In certain embodiments of the method, the isolation region is encapsulated under the spacer layer before, during and after performing the etch process to recess the first fin structure and the second fin structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present.

What is claimed is:

1. A method for manufacturing a semiconductor device, comprising:
forming a first structure and a second structure, wherein each structure comprises alternately stacked first and second semiconductor layers over a semiconductor substrate, wherein a first sidewall of the first structure faces and is separated from a second sidewall of the second structure by a gap;
forming an isolation material in the gap;
forming a spacer layer over the first structure, the isolation material, and the second structure, wherein the spacer layer includes a first upper portion located over the first structure, a second upper portion located over the second structure, a first sidewall portion laterally adjacent to the first sidewall, a second sidewall portion laterally adjacent to the second sidewall, and a lower portion over the isolation material and extending from the first sidewall portion to the second sidewall portion;
depositing a blocking layer over the spacer layer, wherein an upper portion of the blocking layer is located above the first structure and the second structure, and wherein an inter-structure portion of the blocking layer is located between the first structure and the second structure;
removing the upper portion of the blocking layer to uncover the first upper portion and the second upper portion of the spacer layer; and
while the spacer layer remains over the isolation material, performing an etch process to remove the alternately stacked first and second semiconductor layers from over the semiconductor substrate.

2. The method of claim 1, wherein, while performing the etch process to remove the alternately stacked first and second semiconductor layers from over the semiconductor substrate, the first sidewall portion and the second sidewall portion of the spacer layer are reduced in height.

3. The method of claim 1, wherein, after performing the etch process to remove the alternately stacked first and second semiconductor layers from over the semiconductor substrate, the first sidewall portion and the second sidewall portion of the spacer layer terminate at upper surfaces distanced from the lower portion by distances of from 10 to 30 nanometers (nm).

4. The method of claim 1, wherein the lower portion of the spacer layer has a thickness in a direction perpendicular to the semiconductor substrate of from 1 to 15 nanometers (nm).

5. The method of claim 1, wherein, before performing the etch process to remove the alternately stacked first and second semiconductor layers from over the semiconductor substrate, the alternately stacked first and second semiconductor layers have a combined height in a direction perpendicular to the semiconductor substrate of from 30 to 70 nanometers (nm).

6. The method of claim 1, wherein, each sidewall portion of the spacer layer forms an internal angle with the lower portion of the spacer layer of from 80 to 90 degrees.

7. The method of claim 1, wherein the spacer layer is SiN, SiOCN, SiOC, SiO₂, or SiC.

8. The method of claim 1, further comprising selectively growing epitaxial material over the semiconductor substrate of the first structure and over the semiconductor substrate of the second structure to form a source/drain regions, wherein the spacer layer and isolation material cover the first sidewall and the second sidewall to prevent epitaxial growth thereon.

9. The method of claim 8, further comprising removing the spacer layer after selectively growing the epitaxial material to form the source/drain regions.

10. The method of claim 1, wherein:
after forming the first structure and the second structure, each structure comprises an interface between a lowest second semiconductor layer and the semiconductor substrate; and
after forming the isolation material in the gap, the isolation material has an uppermost surface that is lower than each interface.

11. The method of claim 10, wherein, after forming the spacer layer over the first structure, the isolation material, and the second structure, the spacer layer is in contact with the semiconductor substrate of each structure.

12. A method for manufacturing a semiconductor device, comprising:
forming a structure between a first trench and a second trench, wherein the structure has a first sidewall and a second sidewall;
forming an isolation material in the first trench and in the second trench;
forming a spacer layer over the structure and the isolation material, wherein the spacer layer includes an upper portion located over the structure, a first sidewall portion laterally adjacent to the first sidewall, a second sidewall portion laterally adjacent to the second sidewall, a first trench portion over the isolation material in the first trench, and a second trench portion over the isolation material in the second trench;
depositing a blocking layer over the spacer layer, wherein an upper portion of the blocking layer is located above the structure, and wherein a lower portion of the blocking layer is located laterally adjacent to the structure;
removing the upper portion of the blocking layer to uncover the upper portion of the spacer layer;
removing the upper portion of the spacer layer to uncover the structure; and
performing an etch process to recess the structure, wherein the spacer layer remains over the isolation material.

13. The method of claim 12, wherein forming the structure between the first trench and the second trench comprises etching a semiconductor material to form the first trench and the second trench.

14. The method of claim 13, wherein the semiconductor material comprises alternately stacked first and second semiconductor layers and an underlying semiconductor substrate, and wherein etching the first trench and the second trench comprises etching the first trench and the second trench through the alternately stacked first and second semiconductor layers and into the underlying semiconductor substrate.

15. The method of claim 12, wherein performing the etch process to recess the structure comprises recessing the first sidewall portion and the second sidewall portion of the spacer layer.

16. The method of claim 12, wherein performing the etch process to recess the structure comprises removing the lower portion of the blocking layer.

17. A method for manufacturing a semiconductor device, comprising:
forming a first fin structure and a second fin structure, wherein an isolation region is located between the first fin structure and the second fin structure, and wherein a space is located between the first fin structure and the second fin structure and above the isolation region;
depositing a blocking layer over the first fin structure, the isolation region, and the second fin structure, wherein an upper portion of the blocking layer is located above the first fin structure and the second fin structure, and wherein a lower portion of the blocking layer fills the space located between the first fin structure and the second fin structure;
removing the upper portion of the blocking layer; and
while the lower portion of the blocking layer remains over the isolation region, performing an etch process to recess the first fin structure and the second fin structure.

18. The method of claim 17, further comprising:
planarizing an upper surface of the upper portion of the blocking layer;
forming an upper blocking layer over the upper surface of the upper portion of the blocking layer; and
removing the upper blocking layer before removing the upper portion of the blocking layer.

19. The method of claim 17, further comprising:
forming a spacer layer over the first fin structure, the isolation region, and the second fin structure, wherein the blocking layer is deposited over the spacer layer; and
removing upper portions of the spacer layer to uncover the first fin structure and the second fin structure after removing the upper portion of the blocking layer.

20. The method of claim 19, wherein the isolation region is encapsulated under the spacer layer before, during and after performing the etch process to recess the first fin structure and the second fin structure.
